(19) United States
(12) Patent Application Publication
(10) Pub. No.: US 2026/0303061 A1
(43) Pub. Date: Oct. 1, 2026

(54) ACOUSTIC WAVE DEVICE

(71) Applicant: Murata Manufacturing Co., Ltd., Nagaokakyo-shi (JP)

(72) Inventor: Takahiro TSUTAYA, Nagaokakyo-shi (JP)

(21) Appl. No.: 19/573,003

(22) Filed: Mar. 20, 2026

(30) Foreign Application Priority Data
Mar. 26, 2025 (JP) 2025-051457

(51) Int. Cl. H03H 9/25; H03H 9/02; H03H 9/05; H03H 9/10; H03H 9/145

(52) U.S. Cl. CPC H03H 9/25; H03H 9/02559; H03H 9/02866; H03H 9/02984; H03H 9/02992; H03H 9/059; H03H 9/1092; H03H 9/145

(57) ABSTRACT

An acoustic wave device includes a first substrate including first and second major surfaces, a second substrate including third and fourth major surfaces having piezoelectricity, interdigital transducer (IDT) electrodes on the third major surface, a first wire connected to at least one of the IDT electrodes and grounded, and a second wire on one of the major surfaces. The IDT electrodes respectively include first and second busbar electrodes respectively connecting first and second electrode fingers and grounded. The IDT electrodes and the second substrate define a longitudinally coupled resonator. When the first major surface is viewed in plan view, a connecting conductor overlaps the first busbar electrode.

### CROSS REFERENCE TO RELATED APPLICATIONS

This application claims the benefit of priority to Japanese Patent Application No. 2025-051457 filed on Mar. 26, 2025. The entire contents of this application are hereby incorporated herein by reference.

### BACKGROUND OF THE INVENTION

### 1. Field of the Invention

The present invention relates to acoustic wave devices.

### 2. Description of the Related Art

International Publication No. 2018/143045 discloses an acoustic wave filter including a piezoelectric substrate and a cover portion that oppose each other, a plurality of functional elements (interdigital transducer (IDT) electrodes) disposed on the piezoelectric substrate, a wiring pattern connecting the functional elements, provided on the piezoelectric substrate or the cover portion, and a support layer interposed between the piezoelectric substrate and the cover portion. The functional elements and the piezoelectric substrate form a longitudinally coupled resonator.

In the acoustic wave filter disclosed in International Publication No. 2018/143045, however, the IDT electrodes are connected to ground via the wiring pattern on the piezoelectric substrate, the support layer, and the wiring pattern on the cover portion. This configuration may degrade the attenuation characteristics of the longitudinally coupled resonator.

### SUMMARY OF THE INVENTION

Example embodiments of the present invention provide acoustic wave devices each including a longitudinally coupled resonator with improved attenuation characteristics.

An acoustic wave device according to an example embodiment of the present invention includes a first substrate including a first major surface and a second major surface opposite each other, a second substrate including a third major surface and a fourth major surface, the third major surface facing the first major surface, the fourth major surface being opposite the third major surface, the second substrate having piezoelectricity, a plurality of interdigital transducer (IDT) electrodes on the third major surface, a first wire on the third major surface, the first wire being connected to at least one of the plurality of IDT electrodes, the first wire being grounded, a second wire on at least one of the first major surface, the second major surface, and the fourth major surface, and a first connecting conductor and a second connecting conductor connecting the first wire and the second wire. Each of the plurality of IDT electrodes includes a plurality of first electrode fingers and a plurality of second electrode fingers parallel to each other, a first busbar electrode connected to one end of each of the plurality of first electrode fingers, the first busbar electrode being grounded, and a second busbar electrode connected to one end of each of the plurality of second electrode fingers, the second busbar electrode being opposite the first busbar electrode with the plurality of first electrode fingers and the plurality of second electrode fingers interposed between the second busbar electrode and the first busbar electrode. The plurality of IDT electrodes and the second substrate define a longitudinally coupled resonator. When the first major surface and the third major surface are viewed in plan view, at least a portion of the first connecting conductor overlaps the first busbar electrode.

Example embodiments of the present invention provide acoustic wave devices each including a longitudinally coupled resonator with improved attenuation characteristics.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a sectional view of an acoustic wave device according to an example embodiment of the present invention.

FIG. 2A includes a plan view and a sectional view schematically illustrating a first example of an acoustic wave resonator of an acoustic wave device according to an example embodiment of the present invention.

FIG. 2B is a sectional view schematically illustrating a second example of an acoustic wave resonator of an acoustic wave device according to an example embodiment of the present invention.

FIG. 3 illustrates the circuit configuration of an acoustic wave device according to an example embodiment of the present invention.

FIG. 4A is a first plan view of an acoustic wave device according to an example embodiment of the present invention.

FIG. 4B is a second plan view of an acoustic wave device according to an example embodiment of the present invention.

FIG. 4C is a third plan view of an acoustic wave device according to an example embodiment of the present invention.

FIG. 5 is a sectional view of an acoustic wave device according to a first modification of an example embodiment of the present invention.

FIG. 6 is a sectional view of an acoustic wave device according to a second modification of an example embodiment of the present invention.

### DETAILED DESCRIPTION OF THE EXAMPLE EMBODIMENTS

Hereinafter, example embodiments of the present disclosure will be described in detail with reference to the drawings. The example embodiments described below provide comprehensive or specific examples. Details such as numerical values, shapes, materials, elements, and arrangements and connection configurations of the elements provided in the following example embodiments are illustrative and are not intended to limit the present invention.

The drawings are schematically illustrated with necessary emphasis, omissions, or proportion adjustments to show the present invention and do not necessarily represent exact details. Thus, the shapes, positional relationships, and proportions can differ from actual implementations. The same reference numerals are assigned to the same or substantially the same elements across the drawings, and redundant descriptions of these elements can be omitted or simplified.

Terms describing relationships between elements, such as “parallel” and “vertical”, terms indicating an element's shape, such as “rectangular”, and numerical ranges are not meant to convey only precise meanings. These terms and numerical ranges denote meanings that are substantially the same, involving, for example, about several percent differences.

As used in the present disclosure, the term “terminal” refers to a point at which a conductor within an element terminates. When the impedance of a conductor between elements is sufficiently low, the “terminal” is interpreted not only as a single point but also as any point in the conductor between the elements, or as the entire conductor.

As used in the present disclosure, the term “pass band of a filter” refers to the frequency spectrum that can be passed through the filter and is defined as the frequency range between two frequencies at which the power insertion loss increases by about 3 dB from the minimum value.

As used in the present disclosure, the term “principal component of a material” refers to a component that accounts for greater than 50 percent by weight of the material. The principal component may exist in any state of a single crystal, a polycrystal, or an amorphous state, or in a mixed state thereof.

In terms of the layer structure in the present disclosure, the term “a layer A (or a component A) is disposed on a major surface C of a layer B” includes, in addition to an arrangement in which the layer A (or the component A) is disposed in contact with the major surface C of the layer B, an arrangement in which the layer A (or the component A) is disposed above the major surface C without contacting the major surface C (for example, the layer A (or the component A) is stacked on another layer that is disposed in contact with the major surface C).

As used in the present disclosure, the expression “A and B face each other” refers to an arrangement in which A and B are disposed to oppose each other with a space therebetween, whereas the expression “A and B are positioned opposite each other” refers to an arrangement in which A and B are disposed to oppose each other regardless of whether any intervening member is present between A and B.

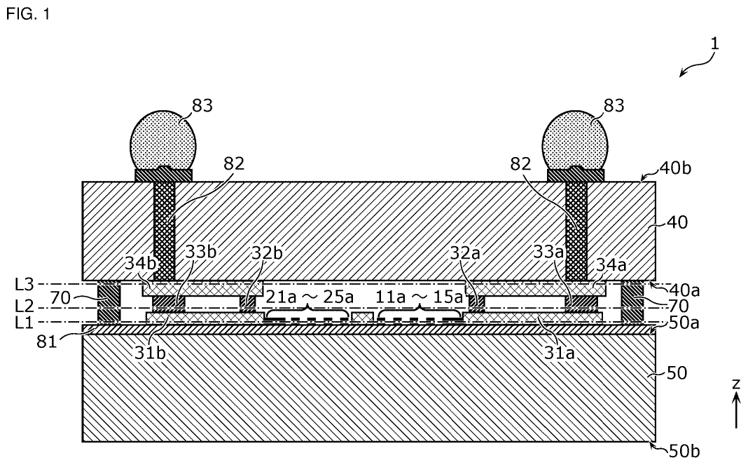

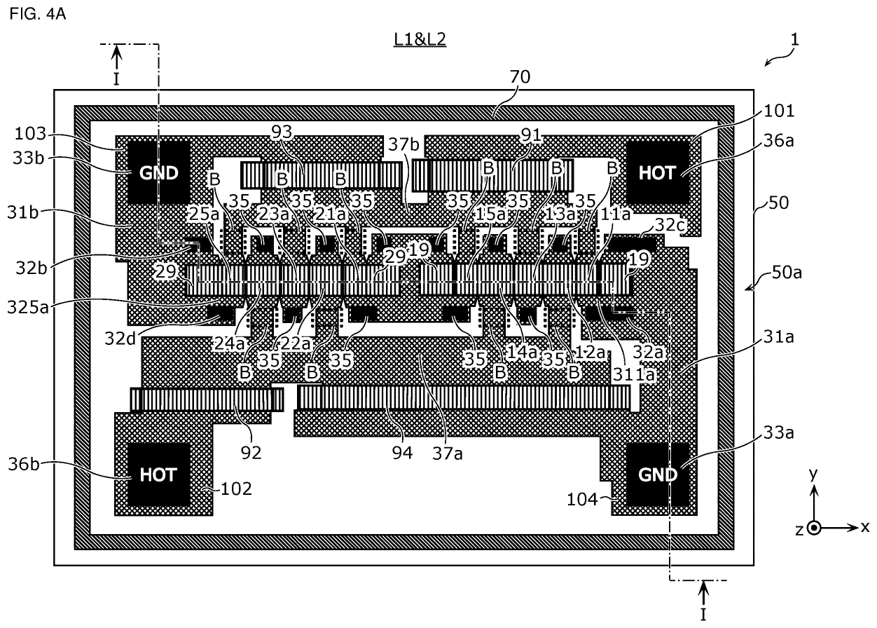

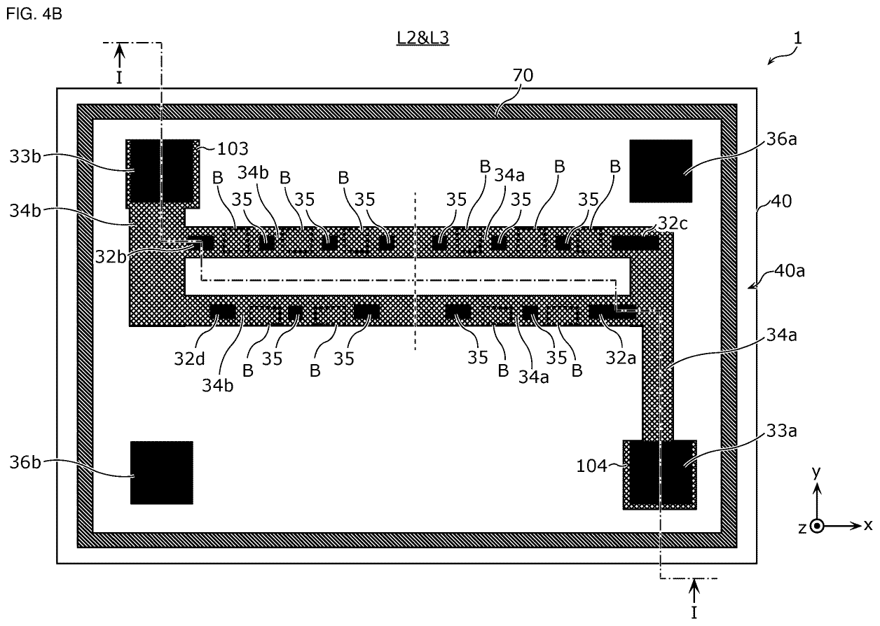

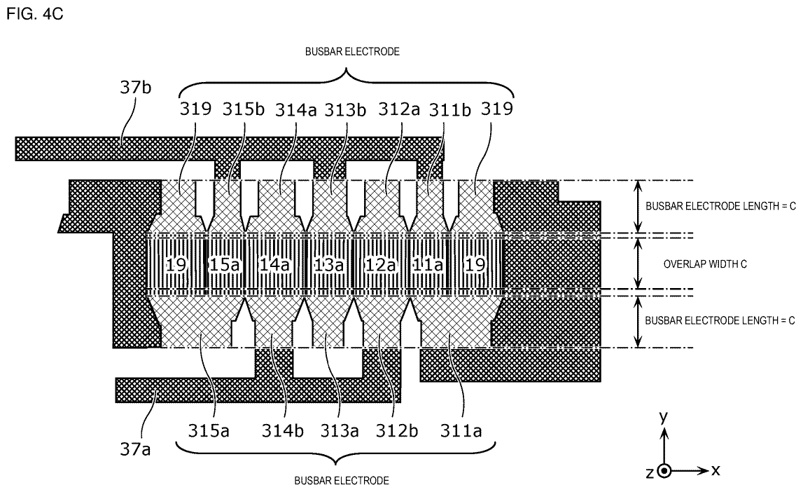

FIG. 1 is a sectional view of an acoustic wave device 1 according to an example embodiment of the present invention. FIG. 1 is a sectional view taken along line I-I in FIGS. 4A and 4B, which will be described later. As illustrated in the drawings, the acoustic wave device 1 includes substrates 40 and 50, interdigital transducer (IDT) electrodes 11a, 12a, 13a, 14a, 15a, 21a, 22a, 23a, 24a, and 25a, wires 31a, 31b, 34a, and 34b, connecting conductors 32a, 32b, 33a, 33b, 35 (not illustrated in FIGS. 1), 36a (not illustrated in FIG. 1), and 36b (not illustrated in FIG. 1), a frame 70, via-conductors 82, an insulating film 81, and bump electrodes 83.

The substrate 40 is an example of a first substrate. The substrate 40 includes a major surface 40a (a first major surface) and a major surface 40b (a second major surface) that are positioned opposite each other. In the present example embodiment, the substrate 40 includes silicon, for example.

The substrate 50 is an example of a second substrate having piezoelectricity. The substrate 50 includes a major surface 50a (a third major surface) and a major surface 50b (a fourth major surface) that are opposite to each other. The major surface 40a faces the major surface 50a.

The IDT electrodes 11a to 15a and 21a to 25a are disposed on the major surface 50a. The insulating film 81 is disposed between the major surface 50a and the IDT electrodes 11a to 15a and 21a to 25a. The insulating film 81 is, for example, a silicon oxide film. The insulating film 81 need not be included.

The wire 31a is an example of a first wire. The wire 31a is disposed on the major surface 50a, is connected to at least one of the IDT electrodes 11a to 15a, and is connected to ground. The wire 31b is an example of a first wire. The wire 31b is disposed on the major surface 50a, is connected to at least one of the IDT electrodes 21a to 25a, and is connected to ground. Each of the wires 34a and 34b is an example of a second wire. The wires 34a and 34b are disposed on the major surface 40a.

The connecting conductor 32a is an example of a first connecting conductor. The connecting conductor 32a is disposed between the major surfaces 40a and 50a and connects the wires 31a and 34a. The connecting conductor 33a is an example of a second connecting conductor. The connecting conductor 33a is disposed between the major surfaces 40a and 50a and connects the wires 31a and 34a. The connecting conductor 32b is disposed between the major surfaces 40a and 50a and connects the wires 31b and 34b. The connecting conductor 33b is disposed between the major surfaces 40a and 50a and connects the wires 31b and 34b. The connecting conductors 32a, 33a, 32b, and 33b are, for example, metal conductors, and may include, for example, a metal such as Ti, Al, Cu, Pt, Au, Ag, or Pd, or an alloy such as AlCu.

The frame 70 is disposed between the major surfaces 40a and 50a, and surrounds the IDT electrodes 11a to 15a and 21a to 25a and the connecting conductors 32a and 32b when the major surfaces 40a and 50a are viewed in plan view.

The via-conductors 82 are disposed within the substrate 40 to connect the major surfaces 40a and 40b. One end of each via-conductor 82 is connected to the wires 34a and 34b at the major surface 40a, and the other end is connected to a corresponding bump electrode 83.

Next, the configuration of acoustic wave resonators of the acoustic wave device 1 is described.

The IDT electrode 11a and the substrate 50 define an acoustic wave resonator 11. The IDT electrode 12a and the substrate 50 define an acoustic wave resonator 12. The IDT electrode 13a and the substrate 50 define an acoustic wave resonator 13. The IDT electrode 14a and the substrate 50 define an acoustic wave resonator 14. The IDT electrode 15a and the substrate 50 define an acoustic wave resonator 15. The IDT electrode 21a and the substrate 50 define an acoustic wave resonator 21. The IDT electrode 22a and the substrate 50 define an acoustic wave resonator 22. The IDT electrode 23a and the substrate 50 define an acoustic wave resonator 23. The IDT electrode 24a and the substrate 50 define an acoustic wave resonator 24. The IDT electrode 25a and the substrate 50 define an acoustic wave resonator 25.

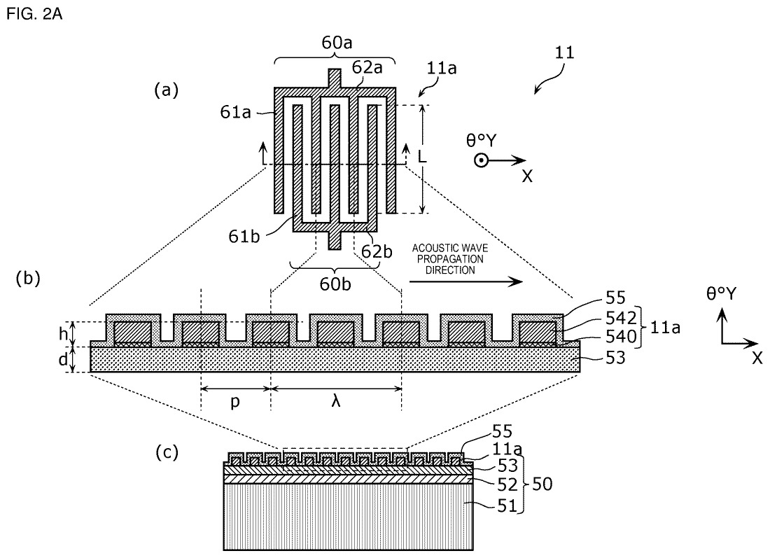

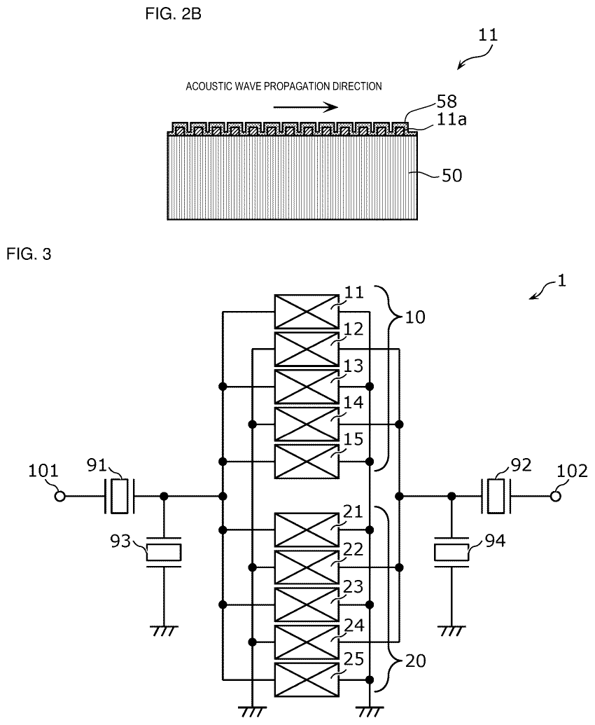

Here, the structure of the acoustic wave resonators 11 to 15 and 21 to 25 is described. FIG. 2A includes a plan view and a sectional view schematically illustrating a first example of the acoustic wave resonator 11 of the acoustic wave device 1 according to the present example embodiment. The drawing illustrates an example of a basic structure of the acoustic wave resonator 11 of the acoustic wave device 1. The acoustic wave resonators 12 to 15 and 21 to 25 also have the same basic structure as the acoustic wave resonator 11. The acoustic wave resonator 11 illustrated in FIG. 2A, as well as the acoustic wave resonators 12 to 15 and 21 to 25, are provided solely to explain a typical structure of an acoustic wave resonator of the acoustic wave device 1. The number and the lengths of electrode fingers defining an electrode, and other specifics are not limited to this example.

As illustrated in FIG. 2A, the acoustic wave resonator 11 includes the substrate 50, the IDT electrode 11a, and a protective layer 55. The protective layer 55 need not be included. The IDT electrode 11a includes comb-shaped electrodes 60a and 60b. A pair of the comb-shaped electrodes 60a and 60b positioned opposite each other is provided on the substrate 50. The comb-shaped electrode 60a includes multiple electrode fingers 61a (first electrode fingers) that are parallel to each other and a busbar electrode 62a (a first busbar electrode) that connects one end of each electrode finger 61a. The comb-shaped electrode 60b includes multiple electrode fingers 61b (second electrode fingers) that are parallel to each other and a busbar electrode 62b (a second busbar electrode) that connects one end of each electrode finger 61b. The electrode fingers 61a and 61b extend in a direction perpendicular to the acoustic wave propagation direction (X-axis direction). The busbar electrodes 62a and 62b are positioned opposite each other with the electrode fingers 61a and 61b interposed therebetween. The busbar electrode 62a is an example of a first busbar electrode. The busbar electrode 62a is connected to ground via the wires 31a, 34a and the connecting conductor 32a.

As illustrated in portion (b) of FIG. 2A, the IDT electrode 11a has a stacked structure including, for example, an adhesion layer 540 and a main electrode layer 542. The adhesion layer 540 is a layer used to improve the firmness of the substrate 50 and the main electrode layer 542 and, for example, Ti is used as a material. As a material of the main electrode layer 542, for example, Al including about 1% Cu may be used. The protective layer 55 covers the comb-shaped electrodes 60a and 60b. The protective layer 55 is used to protect the main electrode layer 542 from the external environment, control frequency-temperature characteristics, and improve moisture resistance. The protective layer 55 is a dielectric film including, for example, silicon dioxide as a principal component.

Materials of the adhesion layer 540, the main electrode layer 542, and the protective layer 55 are not limited to the materials described above. The IDT electrode 11a need not be configured as the stacked structure described above. The IDT electrode 11a may be made of, for example, a metal, such as Ti, Al, Cu, Pt, Au, Ag, or Pd, or an alloy, or may include multiple multilayer bodies made of the metal or alloy.

Next, the stacked structure of the substrate 50 is described.

As illustrated in portion (c) of FIG. 2A, the substrate 50 includes a high acoustic velocity support substrate 51, a low acoustic velocity layer 52, and a piezoelectric layer 53, and has a structure provided by layering the high acoustic velocity support substrate 51, the low acoustic velocity layer 52, and the piezoelectric layer 53 in the order presented.

The piezoelectric layer 53 is made of, for example, a θ° Y-cut X-propagation LiTaO₃ piezoelectric single crystal or piezoelectric ceramic (a lithium tantalate single crystal or ceramic that is cut at a plane perpendicular to a normal line obtained by rotating an axis about an X-axis as a central axis by θ° from a Y-axis and in which surface acoustic waves propagate in the X-axis direction). The material and the cut-angle θ of a piezoelectric single crystal used for the piezoelectric layer 53 are selected as appropriate in accordance with the required specifications of individual filters.

The high acoustic velocity support substrate 51 is an example of a support substrate. The high acoustic velocity support substrate 51 supports the low acoustic velocity layer 52, the piezoelectric layer 53, and the IDT electrode 11a. It is preferable that the acoustic velocity of bulk waves in the high acoustic velocity support substrate 51 is higher than, for example, the acoustic velocity of acoustic waves, such as surface acoustic waves and boundary waves, propagating in the piezoelectric layer 53. The configuration enables surface acoustic waves to be confined in a stack including the piezoelectric layer 53 and the low acoustic velocity layer 52, thus preventing the surface acoustic waves from leaking into a portion beneath the high acoustic velocity support substrate 51.

The high acoustic velocity support substrate 51 includes, for example, silicon. As the material of the high acoustic velocity support substrate 51, for example, a piezoelectric material such as aluminum nitride, lithium tantalate, lithium niobate, or quartz, a ceramic such as alumina, sapphire, magnesia, silicon nitride, silicon carbide, zirconia, cordierite, mullite, steatite, forsterite, spinel, or sialon, a dielectric such as aluminum oxide, silicon oxynitride, diamond-like carbon (DLC), or diamond, or a material including any of the above materials as a principal component may be used. The spinel listed above includes, for example, aluminum compounds including one or more elements such as Mg, Fe, Zn, or Mn, and oxygen. Examples of the spinel listed above include MgAl₂O₄, FeAl₂O₄, ZnAl₂O₄, and MnAl₂O₄. When the high acoustic velocity support substrate 51 includes, for example, silicon, the crystalline state of the silicon is not limited, provided that the acoustic velocity of bulk waves in the high acoustic velocity support substrate 51 is higher than the acoustic velocity of acoustic waves, such as surface acoustic waves and boundary waves, propagating in the piezoelectric layer 53.

The low acoustic velocity layer 52 is an example of an intermediate layer. The low acoustic velocity layer 52 is configured such that the acoustic velocity of bulk waves in the low acoustic velocity layer 52 is lower than, for example, the acoustic velocity of bulk waves propagating in the piezoelectric layer 53. The low acoustic velocity layer 52 is disposed between the piezoelectric layer 53 and the high acoustic velocity support substrate 51. This structure and a property of acoustic waves in which energy is naturally concentrated in low-acoustic-velocity media reduce or prevent leakage of surface acoustic wave energy outside the IDT electrode.

As the material of the low acoustic velocity layer 52, for example, a dielectric material such as silicon oxide, silicon oxynitride, lithium oxide, tantalum oxide, or a compound obtained by adding fluorine, carbon, or boron to silicon oxide, or a material including any of the above materials as a principal component may be used. The silicon oxide may be glass, for example.

By providing the stacked structure of the substrate 50 described above, the Q factor at a resonant frequency and an anti-resonant frequency can be greatly increased in comparison to known structures in which a piezoelectric substrate is used as a single layer. As such, an acoustic wave resonator with a relatively high Q factor can be provided, and as a result, a filter with low insertion loss can be provided by using the acoustic wave resonator.

The high acoustic velocity support substrate 51 may have a structure formed by stacking, for example, a support substrate and a high acoustic velocity layer configured such that bulk waves propagating in the high acoustic velocity layer are faster in velocity than acoustic waves such as surface acoustic waves and boundary waves that propagate in the piezoelectric layer 53. In this case, as the material of the high acoustic velocity layer, the same material as the material of the high acoustic velocity support substrate 51 may be used. As the material of the support substrate, for example, a piezoelectric material such as aluminum nitride, lithium tantalate, lithium niobate, or quartz, a ceramic such as alumina, sapphire, magnesia, silicon nitride, silicon carbide, zirconia, cordierite, mullite, steatite, or forsterite, a dielectric material such as diamond or silicon oxide; a semiconductor such as silicon or gallium nitride, a resin, or a material including any of the above materials as a principal component may be used.

FIG. 2B is a sectional view schematically illustrating a second example of the acoustic wave resonator 11 of the acoustic wave device 1 according to the present example embodiment. The acoustic wave resonator 11 illustrated in FIG. 2A exemplifies a structure in which the IDT electrode 11a is provided on the substrate 50 including the piezoelectric layer 53. However, the substrate 50 on which the IDT electrode 11a is provided may be a piezoelectric single-crystal substrate including a single piezoelectric layer, as illustrated in FIG. 2B.

The piezoelectric single-crystal substrate may be made of, for example, a piezoelectric single crystal of LiNbO₃. The acoustic wave resonator 11 according to the present example includes a piezoelectric single-crystal substrate of LiNbO₃, the IDT electrode 11a, and a protective layer 58 on the piezoelectric single-crystal substrate and the IDT electrode 11a. The protective layer 58 need not be included.

The piezoelectric layer 53 and the piezoelectric single-crystal substrate described above may be modified as appropriate according to, for example, the bandpass characteristics required for the acoustic wave device 1, with respect to parameters such as a stacked structure, material, cut-angle, and thickness. Acoustic wave resonators including, for example, a LiTaO₃ piezoelectric substrate with a cut-angle other than the cut-angle described above can achieve the same or substantially the same advantageous effects as the acoustic wave resonator 11 using the piezoelectric layer 53.

The substrate 50 that has piezoelectricity and on which the IDT electrode 11a is provided may have a structure formed by layering a support substrate, an energy confining layer, and a piezoelectric layer in the order presented. The IDT electrode 11a may be provided on the piezoelectric layer. As the piezoelectric layer, for example, a LiTaO₃ piezoelectric single crystal or a piezoelectric ceramic may be used. The support substrate supports the piezoelectric layer, the energy confining layer, and the IDT electrode 11a.

The energy confining layer includes one or more layers. The velocity of bulk acoustic waves propagating in at least one of the layers is higher than the velocity of acoustic waves propagating near the piezoelectric layer. For example, the energy confining layer may have a stacked structure including a low acoustic velocity layer and a high acoustic velocity layer. The acoustic velocity of bulk waves in the low acoustic velocity layer is lower than the acoustic velocity of acoustic waves propagating in the piezoelectric layer. The acoustic velocity of bulk waves in the high acoustic velocity layer is higher than the acoustic velocity of acoustic waves propagating in the piezoelectric layer. The support substrate may be provided as a high acoustic velocity layer.

The energy confining layer may be, for example, an acoustic impedance layer including a low acoustic impedance layer having a relatively low acoustic impedance and a high acoustic impedance layer having a relatively high acoustic impedance that are alternately layered.

The wavelength λ of the acoustic wave resonator 11 is defined as a repetition period of the electrode fingers 61a or 61b of the IDT electrode 11a illustrated in portion (b) of FIG. 2A. The electrode finger pitch p is about one-half of the wavelength λ and is defined as (W+S), where W is a line width of the electrode fingers 61a and 61b respectively constituting the comb-shaped electrodes 60a and 60b, and S is a space width between adjacent electrode fingers 61a and 61b. The electrode finger duty D of the IDT electrode 11a is a line width occupancy rate of the electrode fingers 61a and 61b and is defined as W/(W+S), which is the ratio of the line width to the sum of the line width W and the space width S. When the spacings between adjacent electrode fingers are not constant in the IDT electrode 11a, the electrode finger pitch p of the IDT electrode 11a is defined as an average electrode finger pitch p_{AVE} of the IDT electrode 11a. The average electrode finger pitch p_{AVE} of the IDT electrode 11a is defined as Di/(Ni−1), where Ni is the total number of electrode fingers 61a and 61b included in the IDT electrode 11a, and Di is a center-to-center distance between the electrode finger located at one end of the IDT electrode 11a and the electrode finger located at the other end in the acoustic wave propagation direction. When the electrode finger duty D is not constant in the IDT electrode 11a, the electrode finger duty D of the IDT electrode 11a is defined as an average electrode finger duty D_{AVE} of the IDT electrode 11a. The average electrode finger duty D_{AVE} of the IDT electrode 11a is defined as W_{ALL}/(W_{ALL}+S_{ALL}), where Ni is the total number of electrode fingers 61a and 61b included in the IDT electrode 11a, W_{ALL} is a total line width obtained by adding the line widths W of a number (Ni−1) of electrode fingers, and S_{ALL} is a total space width obtained by adding the space widths S of a number (Ni−1) of electrode fingers included in the IDT electrode 11a.

The electrode finger pitch p of the comb-shaped electrodes of the IDT electrode 11a can be measured by measuring the line width W and the space width S in a state in which a major surface of the substrate on which the comb-shaped electrodes of the IDT electrode 11a are provided is viewed in plan view and/or in a state in which a section plane extending perpendicular to the extension direction in which the electrode fingers extend is viewed in section view. This measurement can be conducted using a scanning electron microscope (SEM), a scanning transmission electron microscope (STEM), or a transmission electron microscope (TEM), for example.

Next, the circuit configuration of the acoustic wave device 1 is described with reference to FIG. 3. FIG. 3 illustrates an exemplary configuration. The acoustic wave device 1 may be provided using any of various circuit configurations and circuit techniques. Accordingly, the description of the acoustic wave device 1 provided below should not be interpreted as limiting.

FIG. 3 illustrates the circuit configuration of the acoustic wave device 1 according to the present example embodiment. As illustrated in the drawing, the acoustic wave device 1 includes longitudinally coupled resonators 10 and 20, series arm resonators 91 and 92, parallel arm resonators 93 and 94, and input-output terminals 101 and 102.

The series arm resonators 91 and 92 are provided in series in the path connecting the input-output terminals 101 and 102. The parallel arm resonators 93 and 94 are connected between nodes in the path and ground.

The longitudinally coupled resonators 10 and 20 are connected in parallel between the input-output terminals 101 and 102. The longitudinally coupled resonator 10 includes the acoustic wave resonators 11 to 15 arranged in juxtaposition. The IDT electrodes 11a to 15a of the acoustic wave resonators 11 to 15 are disposed on the substrate 50 along the acoustic wave propagation direction. The longitudinally coupled resonator 20 includes the acoustic wave resonators 21 to 25 arranged in juxtaposition. The IDT electrodes 21a to 25a of the acoustic wave resonators 21 to 25 are disposed on the substrate 50 along the acoustic wave propagation direction. In other words, the IDT electrodes 11a to 15a and the substrate 50 define the longitudinally coupled resonator 10, and the IDT electrodes 21a to 25a and the substrate 50 define the longitudinally coupled resonator 20.

The second busbar electrodes of the acoustic wave resonators 11, 13, 15, 21, 23, and 25 are connected to a connection node (HOT) of the series arm resonator 91 and the parallel arm resonator 93, whereas the second busbar electrodes of the acoustic wave resonators 12, 14, 22, and 24 are connected to a connection node (HOT) of the series arm resonator 92 and the parallel arm resonator 94. The first busbar electrodes of the acoustic wave resonators 11, 13, 15, 21, 23, and 25 are connected to ground (GND), and the first busbar electrodes of the acoustic wave resonators 12, 14, 22, and 24 are connected to ground (GND). With the circuit configuration described above, the acoustic wave device 1 defines a longitudinally coupled bandpass filter.

The acoustic wave device 1 according to the present example embodiment need only include at least one of the longitudinally coupled resonators 10 and 20, whereas the series arm resonators 91 and 92 and the parallel arm resonators 93 and 94 need not be included. Furthermore, each of the longitudinally coupled resonators 10 and 20 need only include two or more acoustic wave resonators.

Next, the interconnection structure of the acoustic wave device 1 is described. FIG. 4A is a first plan view of the acoustic wave device 1 according to the present example embodiment. FIG. 4B is a second plan view of the acoustic wave device 1 according to the present example embodiment. FIG. 4C is a third plan view of the acoustic wave device 1 according to the present example embodiment. FIG. 4A is a view (transparent view) as viewed in plan view from the positive side of the z-axis, obtained by superimposing the major surface 50a of the substrate 50 (the plane L1 in FIG. 1) and a plane between the major surfaces 40a and 50a (the plane L2 in FIG. 1). FIG. 4B is a view (transparent view) as viewed in plan view from the positive side of the z-axis, obtained by superimposing the major surface 40a of the substrate 40 (the plane L3 in FIG. 1) and a plane between the major surfaces 40a and 50a (the plane L2 in FIG. 1). FIG. 4C is an enlarged view of the IDT electrodes 11a to 15a and the wires connected to the IDT electrodes 11a to 15a in the plane L1 in FIG. 4A.

As illustrated in FIG. 4A, the IDT electrodes 11a to 15a and 21a to 25a, as well as reflector electrodes 19 and 29, are arranged in juxtaposition along the x-axis direction. The two reflector electrodes 19 are positioned to sandwich the IDT electrodes 11a to 15a, while the two reflector electrodes 29 are positioned to sandwich the IDT electrodes 21a to 25a. As illustrated in FIG. 4C, the IDT electrode 11a includes a busbar electrode 311a (a first busbar electrode) and a busbar electrode 311b (a second busbar electrode). The IDT electrode 12a includes a busbar electrode 312a (a first busbar electrode) and a busbar electrode 312b (a second busbar electrode). The IDT electrode 13a includes a busbar electrode 313a (a first busbar electrode) and a busbar electrode 313b (a second busbar electrode). The IDT electrode 14a includes a busbar electrode 314a (a first busbar electrode) and a busbar electrode 314b (a second busbar electrode). The IDT electrode 15a includes a busbar electrode 315a (a first busbar electrode) and a busbar electrode 315b (a second busbar electrode). The reflector electrodes 19 include busbar electrodes 319. The busbar electrodes 311a, 312b, 313a, 314b, and 315a are arranged in the order presented along the x-axis direction. The busbar electrodes 311b, 312a, 313b, 314a, and 315b are arranged in the order presented along the x-axis direction. This means that the second busbar electrodes set to a signal potential and the first busbar electrodes set to a ground potential are alternately arranged along the x-axis direction.

Although not illustrated in FIG. 4C, similarly to the IDT electrodes 11a to 15a, each of the IDT electrodes 21a to 25a includes the first busbar electrode and the second busbar electrode, and the second busbar electrodes set to a signal potential and the first busbar electrodes set to a ground potential are alternately arranged along the x-axis direction.

The ranges of the first busbar electrodes and the ranges of the second busbar electrodes are defined as follows. In the following, an extension direction in which the first electrode fingers and the second electrode fingers extend is defined as a first direction (the y-axis direction in FIG. 4C), and a direction orthogonal to the extension direction is defined as a second direction (the x-axis direction in FIG. 4C).

The range of a first busbar electrode in the second direction (the width of the first busbar electrode) is a range from an electrode finger located at one end in the second direction, among multiple first electrode fingers and multiple second electrode fingers included in a single IDT electrode, to another electrode finger located at the other end in the second direction. When a reflector electrode is disposed adjacent to an IDT electrode including a first busbar electrode, the range of the first busbar electrode in the second direction is a range from an electrode finger located at one end in the second direction, among multiple first electrode fingers and multiple second electrode fingers included in the IDT electrode and reflector electrode fingers included in the reflector electrode, to another electrode finger located at the other end in the second direction. The range of a first busbar electrode in the first direction (the length of the first busbar electrode) is a range from a connection point between the multiple first electrode fingers and the first busbar electrode to a location spaced away from the first electrode fingers by an overlap width C of the IDT electrode in the first direction.

The range of a second busbar electrode in the second direction (the width of the second busbar electrode) is a range from an electrode finger located at one end in the second direction, among multiple first electrode fingers and multiple second electrode fingers included in a single IDT electrode, to another electrode finger located at the other end in the second direction. The range of a second busbar electrode in the first direction (the length of the second busbar electrode) is a range from a connection point between the multiple second electrode fingers and the second busbar electrode to a location spaced away from the second electrode fingers by an overlap width C of the IDT electrode in the first direction.

As illustrated in FIGS. 4A and 4C, one end of the wire 31a is connected, at the major surface 50a, to the busbar electrode 311a of the IDT electrode 11a and to a busbar electrode 319 of a reflector electrode 19. The wire 31a is disposed on the major surface 50a from the connection portion to a ground terminal 104. One end of the wire 31b is connected, at the major surface 50a, to the busbar electrode 325a of the IDT electrode 25a and to a busbar electrode 329 of a reflector electrode 29. The wire 31b is disposed on the major surface 50a from the connection portion to a ground terminal 103.

The connecting conductor 32a is connected to the busbar electrodes 311a and 319 at the major surface 50a. The connecting conductor 32b is connected to the busbar electrode 329 at the major surface 50a. The connecting conductor 32c is connected to the busbar electrode 319 at the major surface 50a. The connecting conductor 32d is connected to the busbar electrodes 325a and 329 at the major surface 50a.

One end of the wire 34a overlaps the busbar electrodes 311a to 315a when the major surfaces 40a and 50a are viewed in plan view. One end of the wire 34b overlaps the busbar electrodes 321a to 325a in the plan view.

The connecting conductor 33a is connected to the other end of the wire 31a at the major surface 50a and to the other end of the wire 34a at the major surface 40a. The connecting conductor 33b is connected to the other end of the wire 31b at the major surface 50a and to the other end of the wire 34b at the major surface 40a.

The connecting conductors 35 are connected to the busbar electrodes 312a, 314a, 319, 329, 322a, 324a, 313a, 315a, 321a, and 323a at the major surface 50a, and are connected to the wires 34a and 34b at the major surface 40a.

As illustrated in FIG. 4B, the wire 34a is connected to the connecting conductors 32a and 32c at the major surface 40a. The wire 34a is disposed on the major surface 40a from the connection portion to the ground terminal 104. The wire 34b is connected to the connecting conductors 32b and 32d at the major surface 40a. The wire 34b is disposed on the major surface 40a from the connection portion to the ground terminal 103.

In other words, at least a portion of the connecting conductor 32a overlaps the busbar electrode 311a when the major surfaces 40a and 50a are viewed in plan view. In the plan view, at least a portion of the connecting conductor 32c overlaps the busbar electrode 319. In the plan view, at least a portion of the connecting conductor 33a overlaps the ground terminal 104. In the plan view, at least a portion of the connecting conductor 33b overlaps the ground terminal 103.

In this arrangement, the wire 31a is disposed on the major surface 50a from the busbar electrode 311a of the IDT electrode 11a to the ground terminal 104, while the wire 34a is disposed on the major surface 40a from the connecting conductor 32a connected to the busbar electrode 311a to the ground terminal 104. This means that the ground wire connecting the IDT electrode 11a and the ground terminal 104 is provided by the wire 31a disposed on the major surface 50a and the wire 34a disposed on the major surface 40a, which are connected in parallel, along a path from the vicinity of the IDT electrode 11a to the ground terminal 104. This interconnection arrangement, as compared to an arrangement in which a ground wire is disposed only on either the major surface 40a or the major surface 50a, can reduce the parasitic inductance of the ground wire and improve grounding of the longitudinally coupled resonator 10.

At least a portion of the connecting conductor 32b overlaps the busbar electrode 329 when the major surfaces 40a and 50a are viewed in plan view. In the plan view, at least a portion of the connecting conductor 32d overlaps the busbar electrode 325a.

In this arrangement, the wire 31b is disposed on the major surface 50a from the busbar electrode 325a of the IDT electrode 25a to the ground terminal 103, while the wire 34b is disposed on the major surface 40a from the connecting conductor 32d connected to the busbar electrode 325a to the ground terminal 103. This means that the ground wire connecting the IDT electrode 25a and the ground terminal 103 is provided by the wire 31b disposed on the major surface 50a and the wire 34b disposed on the major surface 40a, which are connected in parallel, along a path from the vicinity of the IDT electrode 25a to the ground terminal 103. This interconnection arrangement, as compared to an arrangement in which a ground wire is disposed only on either the major surface 40a or the major surface 50a, can reduce the parasitic inductance of the ground wire and improve grounding of the longitudinally coupled resonator 20.

As a result, the acoustic wave device 1 including the longitudinally coupled resonators 10 and 20 with improved attenuation characteristics is provided.

As illustrated in FIGS. 4A and 4C, the acoustic wave device 1 includes a wire 37a disposed on the major surface 50a, connected to the busbar electrodes 312b, 314b, 322b, and 324b, as well as a wire 37b disposed on the major surface 50a, connected to the busbar electrodes 311b, 313b, 315b, 321b, 323b, and 325b. The wires 37a and 37b are an example of a third wire. The wire 37b is connected to the input-output terminal 101 and the connecting conductor 36a via the series arm resonator 91. The wire 37a is connected to the input-output terminal 102 and the connecting conductor 36b via the series arm resonator 92.

When the major surfaces 40a and 50a are viewed in plan view, the wire 34a overlaps at least one of the wire 37a, the busbar electrode 312b, and the busbar electrode 314b. In the plan view, the wire 34b overlaps at least one of the wire 37a, the busbar electrode 322b, and the busbar electrode 324b. In the plan view, the wire 34a overlaps at least one of the wire 37b, the busbar electrode 311b, the busbar electrode 313b, and the busbar electrode 315b. In the plan view, the wire 34b overlaps at least one of the wire 37b, the busbar electrode 321b, the busbar electrode 323b, and the busbar electrode 325b.

In a case in which the signal wires connecting the longitudinally coupled resonators 10 and 20 to the input-output terminals 101 and 102, as well as the ground wires connecting the longitudinally coupled resonators 10 and 20 to the ground terminals 103 and 104, are disposed only on the major surface 50a, it is necessary to dispose an interlayer insulating film between the signal wires and the ground wires to ensure insulation between the signal wires and the ground wires while the signal wires and the ground wires intersect each other. However, in this case, parasitic capacitance caused by the interlayer insulating film occurs, leading to a problem in which grounding of the longitudinally coupled resonators 10 and 20 is weakened.

In this respect, in the acoustic wave device 1 according to the present example embodiment, the wires 37a and 37b defining and functioning as signal wires are disposed on the major surface 50a, while the wires 34a and 34b defining and functioning as ground wires are disposed on the major surface 40a. As a result, the wires 37a and 37b intersect the wires 34a and 34b in regions B illustrated in FIGS. 4A and 4B, while being spaced apart from each other. This arrangement allows parasitic capacitance generated between the wires 37a and 37b and the wires 34a and 34b to be reduced or prevented. As such, this arrangement can improve grounding of the longitudinally coupled resonators 10 and 20 and improve the attenuation characteristics of the longitudinally coupled resonators 10 and 20.

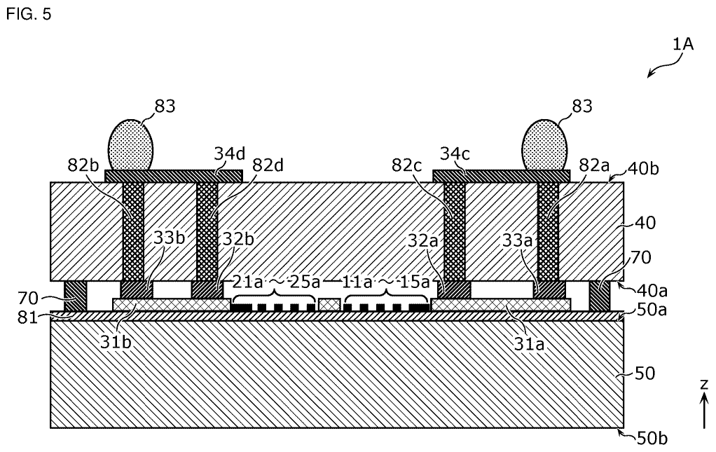

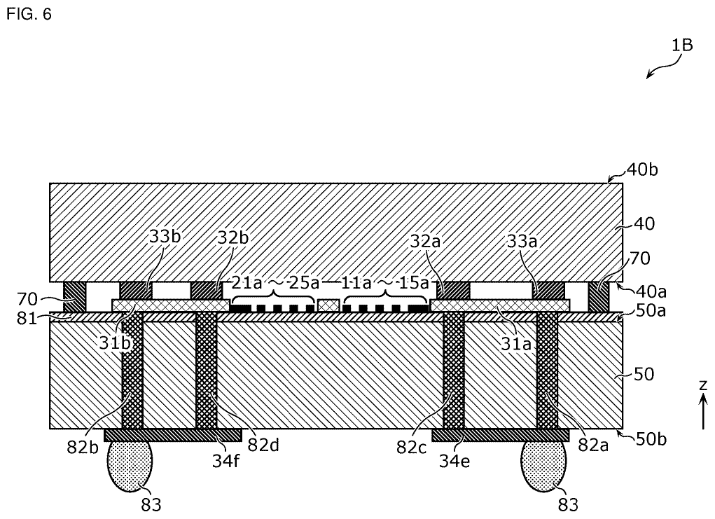

FIG. 5 is a sectional view of an acoustic wave device 1A according to a first modification of an example embodiment of the present invention. As illustrated in FIG. 5, the acoustic wave device 1A includes substrates 40 and 50, IDT electrodes 11a to 15a and 21a to 25a, wires 31a, 31b, 34c, and 34d, connecting conductors 32a, 32b, 33a, 33b, 35 (not illustrated in FIGS. 5), 36a (not illustrated in FIG. 5), and 36b (not illustrated in FIG. 5), a frame 70, via-conductors 82a, 82b, 82c, and 82d, an insulating film 81, and bump electrodes 83. The acoustic wave device 1A according to the present modification differs from the acoustic wave device 1 according to the above-described example embodiment in the arrangement of a second wire (the wires 34c and 34d). The following describes the acoustic wave device 1A according to the present modification with a main focus on the wires 34c and 34d, which are configurational features different from the acoustic wave device 1 according to the above-described example embodiment, and descriptions of the same configurational features as the acoustic wave device 1 according to the above-described example embodiment will not be repeated.

Each of the wires 34c and 34d is an example of a second wire. The wires 34c and 34d are disposed on the major surface 40b. The wires 34c and 34d are connected to the bump electrodes 83 at the major surface 40b.

The connecting conductor 32a is a metal conductor and is disposed between the major surfaces 40a and 50a. The connecting conductor 33a is a metal conductor and is disposed between the major surfaces 40a and 50a.

The via-conductors 82a, 82b, 82c, and 82d are disposed within the substrate 40 to connect the major surfaces 40a and 40b. One end of the via-conductor 82a is connected to the connecting conductor 33a at the major surface 40a, and the other end is connected to the wire 34c at the major surface 40b. One end of the via-conductor 82b is connected to the connecting conductor 33b at the major surface 40a, and the other end is connected to the wire 34d at the major surface 40b. One end of the via-conductor 82c is connected to the connecting conductor 32a at the major surface 40a, and the other end is connected to the wire 34c at the major surface 40b. One end of the via-conductor 82d is connected to the connecting conductor 32b at the major surface 40a, and the other end is connected to the wire 34d at the major surface 40b. The connecting conductor 32a and the via-conductor 82c define a first connecting conductor. The connecting conductor 33a and the via-conductor 82a define a second connecting conductor.

The connecting conductors 32a, 33a, 32b, and 33b are, for example, metal conductors, and may include a metal such as Ti, Al, Cu, Pt, Au, Ag, or Pd, or an alloy such as AlCu.

At least a portion of the connecting conductor 32a overlaps the busbar electrode 311a when the major surfaces 40b and 50a are viewed in plan view. In the above plan view, at least a portion of the connecting conductor 33a overlaps the ground terminal 104.

With this arrangement, the wire 31a is disposed on the major surface 50a from the busbar electrode 311a of the IDT electrode 11a to the ground terminal 104, while the wire 34c is disposed on the major surface 40b from the connecting conductor 32a and the via-conductor 82c connected to the busbar electrode 311a to the ground terminal 104. This means that the ground wire connecting the IDT electrode 11a and the ground terminal 104 is defined by the wire 31a disposed on the major surface 50a and the wire 34c disposed on the major surface 40b, which are connected in parallel, along a path from the vicinity of the IDT electrode 11a to the ground terminal 104. This interconnection arrangement, as compared to an arrangement in which a ground wire is disposed only on either the major surface 40b or the major surface 50a, can reduce the parasitic inductance of the ground wire and improve grounding of the longitudinally coupled resonator 10.

As a result, the acoustic wave device 1A including the longitudinally coupled resonator 10 with an improved attenuation characteristic is provided.

FIG. 6 is a sectional view of an acoustic wave device 1B according to a second modification of an example embodiment of the present invention. As illustrated in FIG. 6, the acoustic wave device 1B includes substrates 40 and 50, IDT electrodes 11a to 15a and 21a to 25a, wires 31a, 31b, 34e, and 34f, connecting conductors 32a, 32b, 33a, 33b, 35 (not illustrated in FIGS. 6), 36a (not illustrated in FIG. 6), and 36b (not illustrated in FIG. 6), a frame 70, via-conductors 82a, 82b, 82c, and 82d, an insulating film 81, and bump electrodes 83. The acoustic wave device 1B according to the present modification differs from the acoustic wave device 1 according to the above-described example embodiment in the arrangement of a second wire (the wires 34e and 34f). The following describes the acoustic wave device 1B according to the present modification with a main focus on the wires 34e and 34f, which are configurational features different from the acoustic wave device 1 according to the above-described example embodiment, and descriptions of the same configurational features as the acoustic wave device 1 according to the above-described example embodiment will not be repeated.

Each of the wires 34e and 34f is an example of a second wire. The wires 34e and 34f are disposed on the major surface 50b. The wires 34e and 34f are connected to the bump electrodes 83 at the major surface 50b.

The connecting conductor 32a is a metal conductor and is disposed between the major surfaces 40a and 50a. The connecting conductor 33a is a metal conductor and is disposed between the major surfaces 40a and 50a.

The via-conductors 82a, 82b, 82c, and 82d are disposed within the substrate 50 to connect the major surfaces 50a and 50b. One end of the via-conductor 82a is connected to the wire 31a at the major surface 50a, and the other end is connected to the wire 34e at the major surface 50b. One end of the via-conductor 82b is connected to the wire 31b at the major surface 50a, and the other end is connected to the wire 34f at the major surface 50b. One end of the via-conductor 82c is connected to the wire 31a at the major surface 50a, and the other end is connected to the wire 34e at the major surface 50b. One end of the via-conductor 82d is connected to the wire 31b at the major surface 50a, and the other end is connected to the wire 34f at the major surface 50b. The via-conductor 82c defines a first connecting conductor. The via-conductor 82a defines a second connecting conductor.

At least a portion of the via-conductor 82c overlaps the busbar electrode 311a when the major surfaces 50a and 50b are viewed in plan view. In the plan view, at least a portion of the via-conductor 82a overlaps the ground terminal 104.

With this arrangement, the wire 31a is disposed on the major surface 50a from the busbar electrode 311a of the IDT electrode 11a to the ground terminal 104, while the wire 34e is disposed on the major surface 50b from the wire 31a and the via-conductor 82c connected to the busbar electrode 311a to the ground terminal 104. This means that the ground wire connecting the IDT electrode 11a and the ground terminal 104 is defined by the wire 31a disposed on the major surface 50a and the wire 34e disposed on the major surface 50b, which are connected in parallel, along a path from the vicinity of the IDT electrode 11a to the ground terminal 104. This interconnection arrangement, as compared to an arrangement in which a ground wire is disposed only on either the major surface 50a or the major surface 50b, can reduce the parasitic inductance of the ground wire and improve grounding of the longitudinally coupled resonator 10.

As a result, the acoustic wave device 1B including the longitudinally coupled resonator 10 with an improved attenuation characteristic is provided.

As described above, the acoustic wave device 1 (1A, 1B) according to the present example embodiment includes the substrate 40 including the major surfaces 40a and 40b that are opposite each other, the substrate 50 including the major surfaces 50a and 50b, the major surface 50a facing the major surface 40a, the major surface 50b being opposite the major surface 50a, the substrate 50 having piezoelectricity, the plurality of IDT electrodes 11a to 15a on the major surface 50a, the wire 31a on the major surface 50a, the wire 31a being connected to at least one of the plurality of IDT electrodes 11a to 15a, the wire 31a being grounded, the wire 34a on the major surface 40a, (the wire 34c disposed on the major surface 40b, the wire 34e disposed on the major surface 50b), and the connecting conductor 32a (the connecting conductor 32a and the via-conductor 82c, the via-conductor 82c) and the connecting conductor 33a (the connecting conductor 33a and the via-conductor 82a, the via-conductor 82a) that connect the wires 31a and 34a (the wire 34c, the wire 34e). Each of the plurality of IDT electrodes 11a to 15a includes the plurality of electrode fingers 61a and the plurality of electrode fingers 61b that are parallel to each other, the busbar electrodes 311a to 315a connected to one end of each of the plurality of electrode fingers 61a, the busbar electrodes 311a to 315a being grounded, and the busbar electrodes 311b to 315b connected to one end of each of the plurality of electrode fingers 61b, the busbar electrodes 311b to 315b being opposite the busbar electrode 311a to 315a with the plurality of electrode fingers 61a and the plurality of electrode fingers 61b interposed between the busbar electrodes 311b to 315b and the busbar electrodes 311a to 315a. The plurality of IDT electrodes 11a to 15a and the substrate 50 define the longitudinally coupled resonator 10. When the major surfaces 40a and 50a are viewed in plan view, at least a portion of the connecting conductor 32a (the connecting conductor 32a and the via-conductor 82c, the via-conductor 82c) overlaps the busbar electrode 311a.

With this arrangement, the wire 31a is disposed on the major surface 50a from the busbar electrode 311a of the IDT electrode 11a to the ground terminal 104, while the wire 34a (the wire 34c, the wire 34e) is disposed on the major surface 40a (the major surface 40b, the major surface 50b) from the connecting conductor 32a (the connecting conductor 32a and the via-conductor 82c, the via-conductor 82c) connected to the busbar electrode 311a to the ground terminal 104. This means that the ground wire connecting the IDT electrode 11a and the ground terminal 104 includes the wire 31a disposed on the major surface 50a and the wire 34a (the wire 34c, the wire 34e) disposed on the major surface 40a (the major surface 40b, the major surface 50b), which are connected in parallel, along a path from the vicinity of the IDT electrode 11a to the ground terminal 104. This interconnection arrangement, as compared to an arrangement in which a ground wire is disposed only on either the major surface 40a (the major surface 40b, the major surface 50b) or the major surface 50a, can reduce the parasitic inductance of the ground wire and improve grounding of the longitudinally coupled resonator 10.

For example, in the acoustic wave device 1 (1A, 1B), one end of the wire 31a is connected to at least one of the plurality of IDT electrodes 11a to 15a, one end of the wire 34a (the wire 34c, the wire 34e) overlaps the busbar electrodes 311a to 315a in the plan view, and the connecting conductor 33a (the connecting conductor 33a and the via-conductor 82a, the via-conductor 82a) is connected to the other end of the wire 31a at the major surface 50a and is connected to the other end of the wire 34a (the wire 34c, the wire 34e) at the major surface 40a (the major surface 40b, the major surface 50b).

With this arrangement, the wire 31a and the wire 34a (the wire 34c, the wire 34e) are connected in parallel along a path from the vicinity of the IDT electrode 11a to the ground terminal 104. This arrangement can reduce the parasitic inductance of the ground wire and improve grounding of the longitudinally coupled resonator 10.

For example, the acoustic wave device 1 further includes the wire 37a disposed on the major surface 50a, the wire 37a being connected to the busbar electrode 312b. The wire 37a overlaps at least one of the wire 34a and the busbar electrode 312b in the plan view.

With this arrangement, the wire 37a defining and functioning as a signal wire is disposed on the major surface 50a, whereas the wire 34a defining and functioning as a ground wire is disposed on the major surface 40a. As a result, the wires 37a and 34a intersect each other with a space between the wires 37a and 34a. This arrangement allows parasitic capacitance generated between the wires 37a and 34a to be reduced or prevented. As such, this arrangement can improve grounding of the longitudinally coupled resonator 10 and improve the attenuation characteristics of the longitudinally coupled resonator 10.

For example, the acoustic wave device 1 further includes the via-conductor 82 disposed within the substrate 40 to connect the major surfaces 40a and 40b. The wire 34a is disposed on the major surface 40a and is connected to the via-conductor 82 at the major surface 40a. Each of the connecting conductors 32a and 33a is a metal conductor disposed between the major surfaces 40a and 50a.

In this arrangement, the wire 31a, which defines and functions as a ground wire and is connected to the IDT electrode 11a, and the wire 34a are disposed to extend in parallel, with a space between the wires 31a and 34a. This arrangement can reduce the parasitic inductance of the ground wire and improve grounding of the longitudinally coupled resonator 10.

For example, in the acoustic wave device 1A, the first connecting conductor includes the connecting conductor 32a disposed between the major surfaces 40a and 50a, and the via-conductor 82c disposed within the substrate 40 to connect the major surfaces 40a and 40b. The second connecting conductor includes the connecting conductor 33a disposed between the major surfaces 40a and 50a, and the via-conductor 82a disposed within the substrate 40 to connect the major surfaces 40a and 40b. The wire 34c is disposed on the major surface 40b and is connected to the via-conductors 82c and 82a at the major surface 40b.

In this arrangement, the wire 31a, which defines and functions as a ground wire and is connected to the IDT electrode 11a, and the wire 34c are disposed to extend in parallel, with a space and the substrate 40 between the wires 31a and 34c. This arrangement can reduce the parasitic inductance of the ground wire and improve grounding of the longitudinally coupled resonator 10.

For example, in the acoustic wave device 1B, the first connecting conductor is the via-conductor 82c disposed within the substrate 50 to connect the major surfaces 50a and 50b, while the second connecting conductor is the via-conductor 82a disposed within the substrate 50 to connect the major surfaces 50a and 50b. The wire 34e is disposed on the major surface 50b and is connected to the via-conductors 82c and 82a at the major surface 50b.

In this arrangement, the wire 31a defining and functioning as a ground wire, connected to the IDT electrode 11a, and the wire 34e are disposed to extend in parallel, with the substrate 50 between the wires 31a and 34e. This arrangement can reduce the parasitic inductance of the ground wire and improve grounding of the longitudinally coupled resonator 10.

For example, in the acoustic wave device 1 (1A, 1B), the substrate 40 includes silicon.

This configuration improves the processing accuracy of the substrate 40.

For example, in the acoustic wave device 1 (1A, 1B), the substrate 50 includes the piezoelectric layer 53 including the major surface 50a and the fifth major surface that are opposite each other, and the high acoustic velocity support substrate 51 disposed on the fifth major surface.

This arrangement greatly increases the Q factor at a resonant frequency and an anti-resonant frequency in comparison to known structures in which a piezoelectric substrate is used as a single layer. As such, an acoustic wave resonator with a relatively high Q factor can be provided, and as a result, a filter with low insertion loss can be provided by using the acoustic wave resonator.

For example, in the acoustic wave device 1 (1A, 1B), the high acoustic velocity support substrate 51 includes at least one material of silicon, aluminum nitride, lithium tantalate, lithium niobate, quartz, alumina, sapphire, magnesia, silicon nitride, silicon carbide, zirconia, cordierite, mullite, steatite, forsterite, spinel, sialon, aluminum oxide, silicon oxynitride, diamond-like carbon (DLC), or diamond.

This configuration reduces or prevents leakage of acoustic wave energy toward the high acoustic velocity support substrate 51.

For example, the acoustic wave device 1 (1A, 1B) further includes the low acoustic velocity layer 52 disposed between the piezoelectric layer 53 and the high acoustic velocity support substrate 51, the low acoustic velocity layer 52 being configured such that the acoustic velocity of bulk waves propagating in the low acoustic velocity layer 52 is lower than the acoustic velocity of bulk waves propagating in the piezoelectric layer 53.

This configuration reduces or prevents leakage of acoustic wave energy to the outside of the IDT electrode.

For example, in the acoustic wave device 1 (1A, 1B), the low acoustic velocity layer 52 includes at least one material of silicon oxide, silicon oxynitride, lithium oxide, tantalum oxide, or a compound obtained by adding fluorine, carbon, or boron to silicon oxide.

This configuration reduces or prevents leakage of acoustic wave energy to the outside of the IDT electrode.

Acoustic wave devices of the present invention have been described with reference to example embodiments and modifications, but the present invention is not limited to the example embodiments and modifications described herein. Partial replacement or combination of the configuration elements presented in the example embodiments and modifications is possible, and the present invention embraces other example embodiments and modifications obtained by making various modifications to the example embodiments that occur to those skilled in the art without departing from the scope of the present invention, and various hardware devices including the acoustic wave devices according to example embodiments of the present invention.

Example embodiments of the present invention can be used as compact acoustic wave devices in a wide variety of communication devices, such as mobile phones, for example.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a first substrate including a first major surface and a second major surface opposite each other;
a second substrate including a third major surface and a fourth major surface, the third major surface facing the first major surface, the fourth major surface being opposite the third major surface, the second substrate having piezoelectricity;
a plurality of interdigital transducer (IDT) electrodes on the third major surface;
a first wire on the third major surface, the first wire being connected to at least one of the plurality of IDT electrodes, the first wire being grounded;
a second wire on at least one of the first major surface, the second major surface, and the fourth major surface; and
a first connecting conductor and a second connecting conductor connected to the first wire and the second wire;
wherein
each of the plurality of IDT electrodes includes:
a plurality of first electrode fingers and a plurality of second electrode fingers extending parallel to each other;
a first busbar electrode connected to one end of each of the plurality of first electrode fingers, the first busbar electrode being grounded; and
a second busbar electrode connected to one end of each of the plurality of second electrode fingers, the second busbar electrode being opposite the first busbar electrode with the plurality of first electrode fingers and the plurality of second electrode fingers interposed between the second busbar electrode and the first busbar electrode;
the plurality of IDT electrodes and the second substrate define a longitudinally coupled resonator; and
when the first major surface and the third major surface are viewed in plan view, at least a portion of the first connecting conductor overlaps the first busbar electrode.

2. The acoustic wave device according to claim 1, wherein
one end of the first wire is connected to at least one of the plurality of IDT electrodes;
one end of the second wire overlaps the first busbar electrode in the plan view; and
the second connecting conductor is connected to another end of the first wire at the third major surface and is connected to another end of the second wire at the first major surface.

3. The acoustic wave device according to claim 1, further comprising:
a third wire on the third major surface, the third wire being connected to the second busbar electrode; wherein
the second wire overlaps at least one of the third wire and the second busbar electrode in the plan view.

4. The acoustic wave device according to claim 1, further comprising:
a via-conductor in the first substrate and connecting the first major surface and the second major surface; wherein
the second wire is on the first major surface and is connected to the via-conductor at the first major surface; and
each of the first connecting conductor and the second connecting conductor is a metal conductor located between the first major surface and the third major surface.

5. The acoustic wave device according to claim 1, wherein
each of the first connecting conductor and the second connecting conductor includes:
a metal conductor between the first major surface and the third major surface; and
a via-conductor in the first substrate and connecting the first major surface and the second major surface; and
the second wire is on the second major surface and is connected to the via-conductor at the second major surface.

6. The acoustic wave device according to claim 1, wherein
each of the first connecting conductor and the second connecting conductor includes a via-conductor in the second substrate and connecting the third major surface and the fourth major surface; and
the second wire is on the fourth major surface and is connected to the via-conductor at the fourth major surface.

7. The acoustic wave device according to claim 1, wherein the first substrate includes silicon.

8. The acoustic wave device according to claim 1, wherein
the second substrate includes:
a piezoelectric layer including the third major surface and a fifth major surface opposite each other; and
a support substrate on the fifth major surface.

9. The acoustic wave device according to claim 8, wherein the support substrate includes at least one of silicon, aluminum nitride, lithium tantalate, lithium niobate, quartz, alumina, sapphire, magnesia, silicon nitride, silicon carbide, zirconia, cordierite, mullite, steatite, forsterite, spinel, sialon, aluminum oxide, silicon oxynitride, diamond-like carbon (DLC), or diamond.

10. The acoustic wave device according to claim 8, further comprising an intermediate layer between the piezoelectric layer and the support substrate, the intermediate layer being configured such that an acoustic velocity of bulk waves propagating in the intermediate layer is lower than an acoustic velocity of bulk waves propagating in the piezoelectric layer.

11. The acoustic wave device according to claim 8, further comprising:
an intermediate layer between the piezoelectric layer and the support substrate; wherein
the intermediate layer includes at least one of silicon oxide, silicon oxynitride, lithium oxide, tantalum oxide, or a compound obtained by adding fluorine, carbon, or boron to silicon oxide.

12. The acoustic wave device according to claim 1, wherein each of the plurality of IDT electrodes includes an adhesion layer and a main electrode layer on the adhesion layer.

13. The acoustic wave device according to claim 12, wherein the adhesion layer includes Ti.

14. The acoustic wave device according to claim 12, wherein the main electrode layer includes Al including about 1% Cu.

15. The acoustic wave device according to claim 1, further comprising a protective layer covering the plurality of IDT electrodes.

16. The acoustic wave device according to claim 15, wherein the protective layer includes silicon dioxide as a principal component.

17. The acoustic wave device according to claim 8, wherein the piezoelectric layer includes a θ° Y-cut X-propagation LiTaO₃ piezoelectric single crystal or piezoelectric ceramic.

18. The acoustic wave device according to claim 1, wherein each of the plurality of IDT electrodes includes Ti, Al, Cu, Pt, Au, Ag, or Pd, or an alloy including at least one of Ti, Al, Cu, Pt, Au, Ag, or Pd.
